(19) United States
(12) Patent Application Publication
(10) Pub. No.: US 2024/0172493 A1
(43) Pub. Date: May 23, 2024

(54) THIN FILM TRANSISTOR SUBSTRATE, DISPLAY DEVICE INCLUDING THE SAME, AND MANUFACTURING METHODS THEREOF

(71) Applicant: LG Display Co., Ltd., Seoul (KR)

(72) Inventors: Young Hyun KO, Paju-si (KR); Ju Heyuck BAECK, Paju-si (KR); Do Hyung LEE, Paju-si (KR); Hong Rak CHOI, Paju-si (KR); Chan Yong JEONG, Paju-si (KR)

(21) Appl. No.: 18/473,021

(22) Filed: Sep. 22, 2023

(30) Foreign Application Priority Data
Nov. 18, 2022 (KR) 10-2022-0155500

(51) Int. Cl. H10K 59/126; H10K 59/12; H10K 59/124

(52) U.S. Cl. CPC H10K 59/126; H10K 59/1201; H10K 59/124

(57) ABSTRACT

An organic light emitting display device, in which a silicon semiconductor pattern is formed on a buffer layer, and light shielding patterns of a pixel driving thin film transistor and a switching thin film transistor are then formed in the same process by processing portions of the silicon semiconductor pattern such that the portions of the silicon semiconductor pattern have conductivity, is disclosed. In a procedure of forming the silicon semiconductor pattern for formation of the light shielding patterns, a silicon semiconductor pattern, which is disposed under a gate driving thin film transistor, may be formed simultaneously with the former silicon semiconductor pattern, without using an additional silicon semiconductor pattern formation procedure. Accordingly, stack structures, planar design, and processes are simplified and, as such, there are effects of preventing failure occurring due to processes while reducing tact time and costs.

### CROSS-REFERENCE TO RELATED APPLICATION(S)

This application claims the benefit of Korean Patent Application No. 10-2022-00155500, filed on Nov. 18, 2022, which is hereby incorporated by reference as if fully set forth herein.

### BACKGROUND

### Technical Field

The present disclosure relates to a thin film transistor substrate in which thin film transistors of different types are disposed on the same substrate, and a display device using the same, and more particularly to a thin film transistor substrate in which semiconductor patterns formed in the same process are used as a light shielding pattern or an active pattern in thin film transistors of different types, respectively, and an organic light emitting display device using the same.

### Description of the Related Art

In accordance with advances in information-dependent society, the importance of an image display device has increased. Such a display device has rapidly been changed from a cathode-ray tube (CRT) display device using a CRT and having a large volume to a flat display device capable of having a large area while having a thin and light structure.

In addition, in recent years, products having excellent portability and wearability have been developed as display devices in accordance with active development of personal electronic appliances. In connection with this, requirement for a display device with low power consumption is increased in order to not only enhance response time, luminous efficacy, brightness, and viewing angle, but also to enhance portability.

### BRIEF SUMMARY

In a display device including an oxide semiconductor thin film transistor, a light shielding pattern is disposed between a substrate and the oxide semiconductor thin film transistor, and the light shielding pattern is electrically connected to an active pattern and a source-drain electrode and, as such, it may be possible to increase a saturation effect of a drain current flowing through the active pattern, and to maintain the drain current at a predetermined value even when there is a variation in drain voltage. However, the light shielding pattern is formed on a layer different from that of the oxide semiconductor thin film transistor. For this reason, an additional mask is required for a formation process for the light shielding pattern. Accordingly, the present disclosure is directed to a thin film transistor substrate, a display device including the same, and manufacturing methods thereof that substantially obviate one or more problems due to limitations and disadvantages of the related art.

Various embodiments of the present disclosure provide a thin film transistor substrate enabling a light shielding pattern to be formed simultaneously with an active pattern of a polycrystalline silicon thin film transistor, thereby being capable of achieving formation of a light shielding pattern disposed under an oxide semiconductor thin film transistor without using an additional mask, and an organic light emitting display device including the same.

Additional advantages, technical benefits, and features of the disclosure will be set forth in part in the description which follows and in part will become apparent to those having ordinary skill in the art upon examination of the following or may be learned from practice of the disclosure. The benefits and other advantages of the disclosure may be realized and attained by the structure particularly pointed out in the written description and claims hereof as well as the appended drawings.

To achieve these benefits and other advantages and in accordance with the purpose of the disclosure, as embodied and broadly described herein, an organic light emitting display device includes a thin film transistor substrate including a substrate including an display area and a non-display area provided around the display area, a buffer layer provided on the substrate while including at least one inorganic insulating layer, a first insulating layer provided on the buffer layer while including at least one inorganic insulating layer, a second insulating layer provided on the first insulating layer while including at least one inorganic insulating layer, a pixel driving thin film transistor provided in the display area, a gate driving thin film transistor provided in the non-display region, a switching thin film transistor provided in the display area, and a capacitor electrically connected to the driving thin film transistor.

In accordance with an embodiment of the present disclosure, the pixel driving thin film transistor may include a first active pattern provided on the first insulating layer, a first gate electrode provided on the second insulating layer while overlapping with the first active pattern, a first light shielding pattern provided under the first active pattern while overlapping with the first active pattern, and a first source electrode and a first drain electrode electrically connected to the first active pattern. The first active pattern and the first light shielding pattern may be electrically connected to the first source electrode. The first active pattern may include an oxide semiconductor material. The first light shielding pattern may include a semiconductor material having conductivity.

In accordance with an embodiment of the present disclosure, the gate driving thin film transistor may include a second active pattern formed on the buffer layer, and a second gate electrode provided on the first insulating layer. The second active pattern may include a polycrystalline semiconductor material. The second gate electrode may include an oxide semiconductor material having conductivity.

In accordance with an embodiment of the present disclosure, the switching thin film transistor may include a second light shielding pattern provided on the buffer layer, a third active pattern provided on the first insulating layer, and a third gate electrode overlapping with the third active pattern on the second insulating layer. The third active pattern may include an oxide semiconductor material. The second active pattern may include a semiconductor material having conductivity. The second light shielding pattern and the third gate electrode may be electrically interconnected.

In accordance with an embodiment of the present disclosure, each of the first light shielding pattern and the second light shielding pattern may include a polycrystalline semiconductor material doped with P-type ions.

In accordance with an embodiment of the present disclosure, the capacitor may include a first capacitor electrode including an oxide semiconductor material having conductivity, and a second capacitor electrode including a polycrystalline silicon semiconductor material having conductivity.

In accordance with an embodiment of the present disclosure, the first capacitor electrode may be formed on the first insulating layer, and the second capacitor electrode may be formed on the buffer layer.

In accordance with an embodiment of the present disclosure, the second active pattern, the first light shielding pattern, the second light shielding pattern, and the second capacitor electrode may be formed on the same layer and constituted by the same material.

In accordance with an embodiment of the present disclosure, the second gate electrode, the first active pattern, and the first capacitor electrode may be formed on the same layer and constituted by the same material.

In accordance with an embodiment of the present disclosure, the first active pattern may include an N-type semiconductor material, and the first light shielding pattern may include a P-type semiconductor material.

In another aspect of the present disclosure, there is provided an organic light emitting display device including a third insulating layer provided on a second insulating layer, a first planarization layer provided on the third insulating layer, and a second planarization layer provided on the first planarization layer. An anode may be provided on the second planarization layer. An organic light emitting layer may be provided on the anode. A cathode may be provided on the organic light emitting layer. The organic light emitting display device may further include an anode connection electrode configured to electrically interconnect a common voltage line and the cathode in a non-display area.

In another aspect of the present disclosure, there is provided a method of manufacturing a thin film transistor substrate, including forming a buffer layer including at least one inorganic insulating layer on a substrate, forming a first light shielding pattern and a second active pattern on the first buffer layer, forming a first insulating layer including at least one inorganic insulating layer on the first light shielding pattern and the second active pattern, forming a first active pattern overlapping with the first light shielding pattern and a second gate electrode overlapping with the second active pattern on the first insulating layer, forming a second insulating layer on the first active pattern and the second gate electrode, forming a first gate electrode overlapping with the first active pattern on the second insulating layer, forming a third insulating layer on the first gate electrode and the second insulating layer, and forming a first source electrode, a first drain electrode, a second source electrode, and a second drain electrode on the third insulating layer, wherein the first light shielding pattern and the first active pattern are electrically connected to the first source electrode and the first drain electrode electrically connected to each other, wherein the second source electrode and the second drain electrode are electrically connected to the second active pattern, wherein each of the first active pattern and the second gate electrode includes an oxide semiconductor material, and wherein each of the first light shielding pattern and the second active pattern includes a silicon semiconductor material.

In accordance with an embodiment of the present disclosure, the method may further include forming a first electrode, and forming a second electrode. The second electrode may be formed on the same layer as that of the first light shielding pattern, and the first electrode may be formed on the same layer as that of the first active pattern.

In accordance with an embodiment of the present disclosure, the method may further include forming a second light shielding pattern, forming a third active pattern, forming a third gate electrode, and forming a third source electrode and a third drain electrode. The second light shielding pattern may be formed on the same layer as that of the first light shielding pattern. The third gate electrode may be formed on the same layer as that of the first gate electrode. The third source electrode and the third drain electrode may be formed on the same layer as that of the first source electrode and the first drain electrode.

In another aspect of the present disclosure, there is provided a method of manufacturing an organic light emitting display device further including, in addition to the above-described thin film transistor substrate manufacturing method, forming a first planarization layer on the third insulating layer, forming a second planarization layer on the first planarization layer, forming an anode on the second planarization layer, forming an organic light emitting layer on the anode, and forming a cathode on the organic light emitting layer, wherein the anode is electrically connected to the first drain electrode.

The problems to be solved, the solutions to the problems, and the effects described above do not specify essential features of the appended claims and, as such, the scope of the claims is not limited to the matters described in the disclosure.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a schematic block diagram of a display device according to an exemplary embodiment of the present disclosure;

FIG. 2 is a schematic block diagram of one sub-pixel of the display device according to the exemplary embodiment of the present disclosure;

FIG. 3 is a circuit diagram of one sub-pixel of the display device according to the exemplary embodiment of the disclosure;

FIG. 4A is a cross-sectional view showing a gate driving thin film transistor disposed on a substrate, and a pixel driving thin film transistor, a switching thin film transistor, and a storage capacitor disposed in an display area in accordance with a first embodiment of the present disclosure;

FIGS. 4B, 4C, 4D, and 4E are cross-sectional views explaining procedures of forming the thin film transistors and the storage capacitor disposed on the substrate according to the exemplary embodiment of the present disclosure; and

FIG. 5 is a cross-sectional view showing a pixel driving thin film transistor and a storage capacitor according to a second embodiment of the present disclosure.

### DETAILED DESCRIPTION

Advantages and features of the present disclosure and methods for achieving the same will be made clear from embodiments described below in detail with reference to the accompanying drawings. The present disclosure may, however, be embodied in many different forms, and should not be construed as being limited to the embodiments set forth herein. Rather, these embodiments are provided so that this disclosure will be thorough and complete, and will fully convey the scope of the disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the present specification, the same reference numerals designate the same constituent elements. In addition, in the following description of the present disclosure, a detailed description of known functions and configurations incorporated herein will be omitted when it may make the subject matter of the present disclosure rather unclear. The terms “comprises,” “includes,” and/or “has,” used in this specification, do not preclude the presence or addition of other elements unless used along with the term “only.” The singular forms are intended to include the plural forms as well, unless the context clearly indicates otherwise.

In the interpretation of constituent elements included in the various embodiments of the present disclosure, the constituent elements are interpreted as including an error range even if there is no explicit description thereof.

In the description of the various embodiments of the present disclosure, when describing positional relationships, for example, when the positional relationship between two parts is described using “on,” “above,” “below,” “next to,” or the like, one or more other parts may be located between the two parts unless the term “directly” or “closely” is used.

In the description of the various embodiments of the present disclosure, when describing temporal relationships, for example, when the temporal relationship between two actions is described using “after,” “subsequently,” “next,” “before,” or the like, the actions may not occur in succession unless the term “directly” or “just” is used therewith.

In the description of the various embodiments of the present disclosure, when describing signal flow relationships, for example, when a signal is transmitted from a node A to a node B, this case may include the case in which the signal is transmitted from the node A to the node B via another node, unless the term “directly” or “just” is used therewith.

It may be understood that, although the terms “first,” “second,” etc., may be used herein to describe various elements, these elements are not to be limited by these terms. These terms are merely used to distinguish one element from another. Therefore, in the present specification, an element indicated by “first” may be the same as an element indicated by “second” without exceeding the technical scope of the present disclosure, unless otherwise mentioned.

The respective features of the various embodiments of the present disclosure may be partially or entirely coupled to and combined with each other, and various technical linkages and modes of operation thereof are possible. These various embodiments may be performed independently of each other, or may be performed in association with each other.

Hereinafter, various configurations of a substrate including a thin film transistor according to a first embodiment of the present disclosure and a display device using the same will be described.

### First Embodiment

Hereinafter, the first embodiment of the present disclosure will be described with reference to the accompanying drawings.

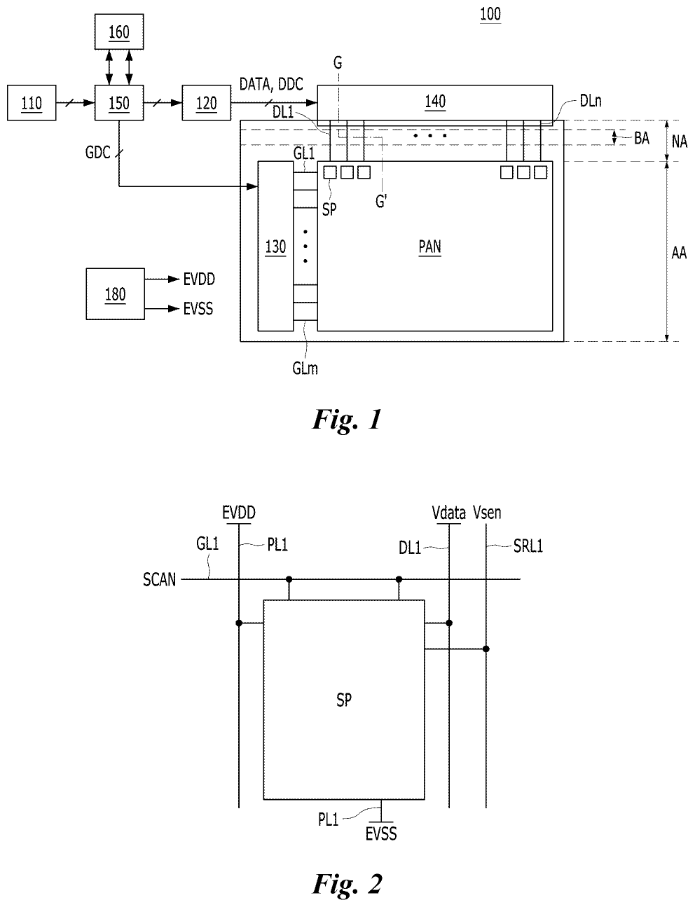

FIG. 1 is a schematic block diagram of a display device 100 according to an exemplary embodiment of the present disclosure.

FIG. 2 is a schematic block diagram of a sub-pixel SP shown in FIG. 1.

As shown in FIG. 1, the display device 100 includes an image processor 110, a degradation compensator 150, a memory 160, a timing controller 120, a data driver 140, a power supply 180, a gate driver 130, and a display panel PAN. At least one of the image processor 110, the degradation compensator 150, the memory 160, the timing controller 120, the data driver 140, the power supply 180, or the gate driver 130 may be formed in a non-display area NA of the display panel PAN. The non-display area NA of the display panel PAN may include a bending area BA. The display panel PAN may be folded in the bending area BA and, as such, may reduce a bezel.

The image processor 110 outputs drive signals for driving various devices, together with image data supplied from an exterior thereof.

The degradation compensator 150 modulates input image data Idata of each sub-pixel SP of a current frame based on a sensing voltage Vsen supplied from the data driver 140, and then supplies the modulated image data, that is, data Mdata, to the timing controller 120.

The timing controller 120 generates and outputs a gate timing control signal GDC for control of operation timing of the gate driver 130 and a data timing control signal DDC for control of operation timing of the data driver 140 based on a drive signal input from the image processor 110 thereto.

The gate driver 130 outputs a scan signal to the display panel PAN in response to the gate timing control signal GDC supplied from the timing controller 120. The gate driver 130 outputs the scan signal through a plurality of gate lines GL1 to GLm. In particular, the gate driver 130 may be configured to have a gate-in-panel (GIP) structure in which a thin film transistor is stacked on a substrate of the display panel PAN. The GIP may include a plurality of circuits such as a shift register, a level shifter, etc.

The data driver 140 outputs a data voltage to the display panel PAN in response to the data timing control signal DDC input from the timing controller 120 thereto. The data driver 140 outputs the data voltage through a plurality of data lines DL1 to DLn.

The power supply 180 outputs a high-level drive voltage EVDD, a low-level drive voltage EVSS, etc., and supplies the high-level drive output voltages EVDD, the low-level drive voltage EVSS, etc., to the display panel PAN. The high-level drive voltage EVDD and the low-level drive voltage EVSS are supplied to the display panel PAN through power lines.

The display panel PAN displays an image, corresponding to the data voltage supplied from the data driver 140, the scan signal supplied from the gate driver 130, and power supplied from the power supply 180.

An display area AA of the display panel PAN is constituted by a plurality of sub-pixels SP and, as such, displays an actual image. The sub-pixels SP include a red (R) sub-pixel, a green (G) sub-pixel, and a blue (B) sub-pixel, or include a white (W) sub-pixel, a red (R) sub-pixel, a green (G) sub-pixel, and a blue (B) sub-pixel. In this case, the W. R. G, and B sub-pixels SP may be formed to have the same area or may be formed to have different areas, respectively.

The memory 160 not only stores a look-up table for degradation compensation gains, but also stores a degradation compensation time point of a light emitting element of each sub-pixel SP. In this case, the degradation compensation time point of the light emitting element may be the number of times when the display panel PAN is driven or the time for which the display panel PAN is driven.

Meanwhile, as shown in FIG. 2, each sub-pixel SP may be connected to one gate line, for example, the gate line GL1, one data line, for example, the data line DL1, one sensing voltage read-out line, for example, a sensing voltage read-out line SRL1, and one power line, for example, a power line PL1. The numbers of transistors and capacitors of the sub-pixel SP and the driving method of the sub-pixel SP are determined in accordance with a circuit configuration of the sub-pixel SP.

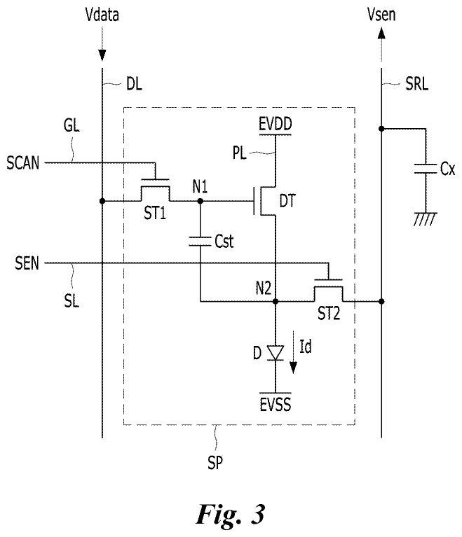

FIG. 3 is a circuit diagram of one sub-pixel SP of the display device 100 according to the exemplary embodiment of the disclosure.

As shown in FIG. 3, the display device 100 according to the exemplary embodiment of the disclosure includes a gate line GL, a data line DL, a power line PL, and a sensing line SL intersecting one another, thereby defining a sub-pixel SP, and includes a driving thin film transistor DT, a light emitting element D, a storage capacitor Cst, a first switching thin film transistor ST1, and a second switching thin film transistor ST2 at the sub-pixel SP.

The light emitting element D may include an anode connected to a second node N2, a cathode connected to an input terminal for a low-level drive voltage EVSS, and an organic light emitting layer disposed between the anode and the cathode.

The driving thin film transistor DT controls current Id flowing through the light emitting element D in accordance with a gate-source voltage Vgs thereof. The driving thin film transistor DT includes a gate electrode connected to a first node N1, a drain electrode connected to the power line PL, to receive a high-level drive voltage EVDD, and a source electrode connected to the second node N2.

The storage capacitor Cst is connected between the first node N1 and the second node N2.

When the display panel PAN is driven, the first switching thin film transistor ST1 applies a data voltage Vdata charged in the data line DL to the first node N1 in response to a scan signal SCAN, thereby turning on the driving thin film transistor DT. In this case, the first switching thin film transistor ST1 includes a gate electrode connected to the gate line GL, to receive the scan signal SCAN, a drain electrode connected to the data line DL, to receive the data voltage Vdata, and a source electrode connected to the first node N1. The first switching thin film transistor ST1 is known as more sensitively operating than other switching thin film transistors in the pixel. To this end, it is necessary to increase a threshold voltage of the first switching thin film transistor ST1, for easy control of the first switching thin film transistor ST1.

The second switching thin film transistor ST2 stores a source voltage of the second node N2 in a sensing capacitor Cx of a sensing voltage read-out line SRL by switching current between the second node N2 and the sensing voltage read-out line SRL in response to a sensing signal SEN. The second switching thin film transistor ST2 resets a source voltage of the driving thin film transistor DT to an initialization voltage Vpre by switching current between the second node N2 and the sensing voltage read-out line SRL in response to the sensing signal SEN when the display panel PAN is driven. In this case, in the second switching thin film transistor ST2, a gate electrode thereof is connected to the sensing line SL, a drain electrode thereof is connected to the second node N2, and a source electrode thereof is connected to the sensing voltage read-out line SRL.

Meanwhile, although a display device having a 3TIC structure including three thin film transistors and one storage capacitor has been illustrated and described, the display device of the present disclosure may be applied to various pixel structures such as 4TIC, 5TIC, 6TIC, 7TIC, and 8TIC without being limited to the above-described structure.

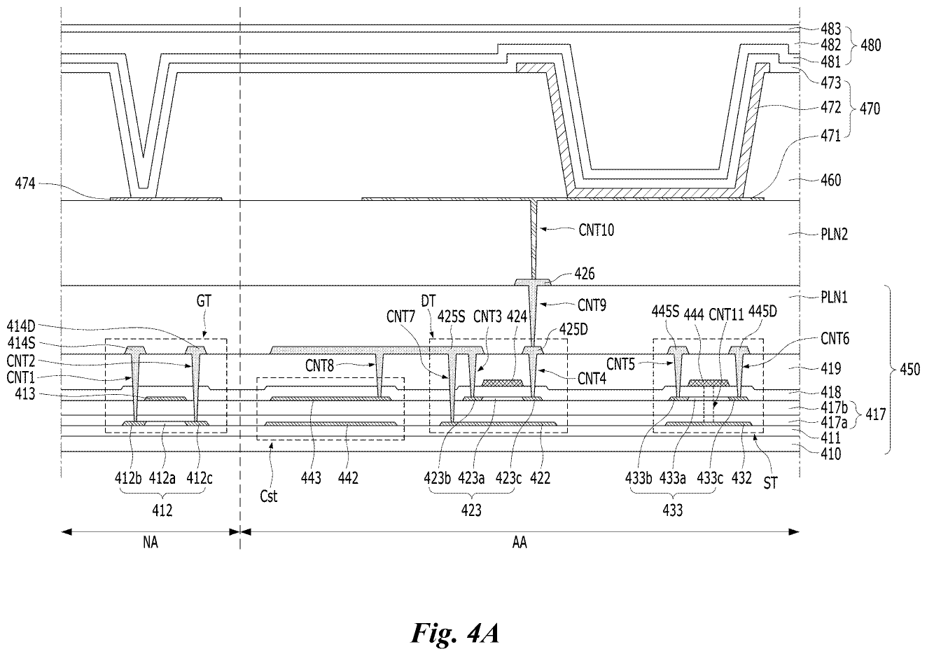

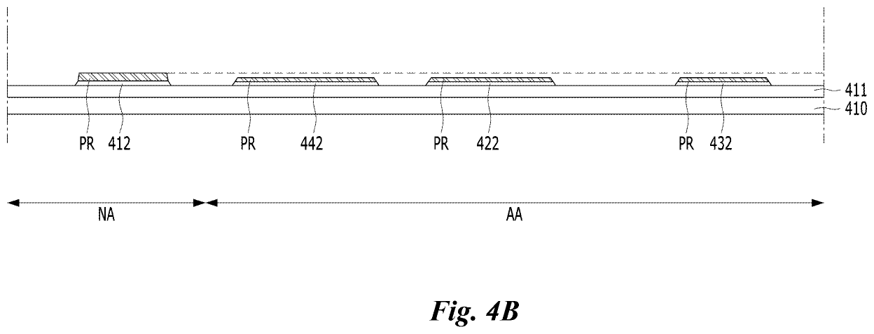

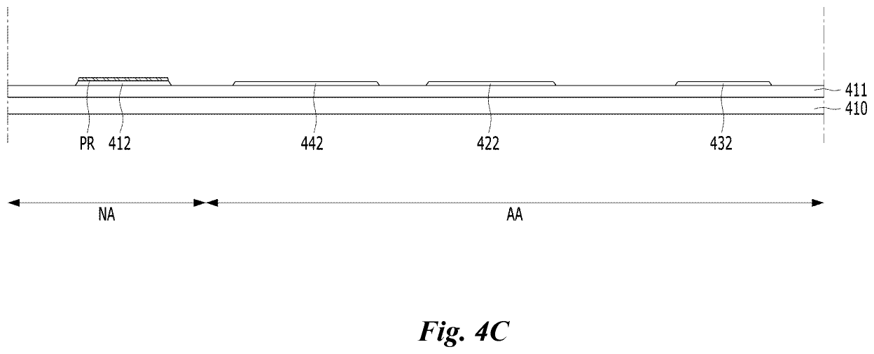

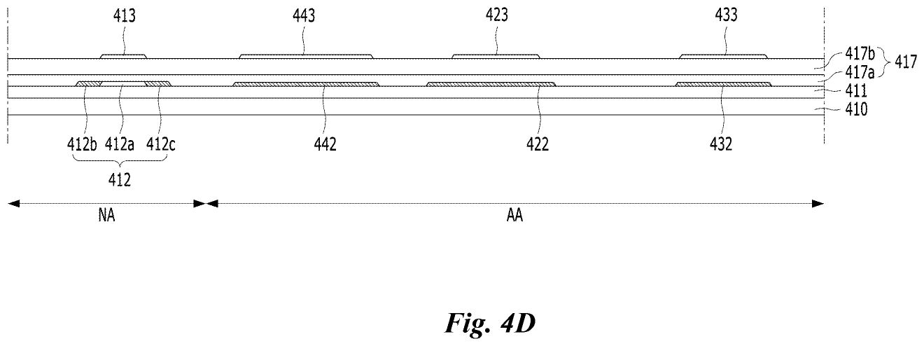

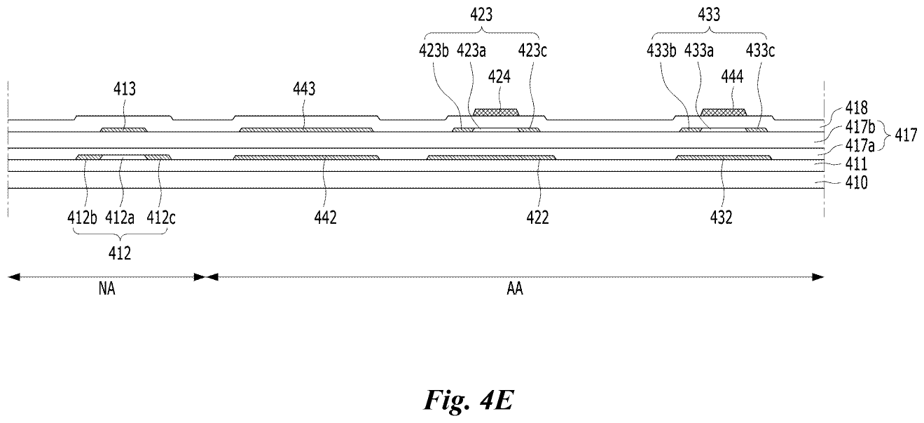

The first embodiment of the present disclosure will be described with reference to FIG. 4A. FIG. 4A is a cross-sectional view showing a thin film transistor substrate for a display device including thin film transistors of different types in accordance with the first embodiment of the present disclosure.

The thin film transistor substrate according to the first embodiment of the present disclosure includes a pixel driving thin film transistor DT and a switching thin film transistor ST disposed in an display area AA of a substrate 410, and a gate driving thin film transistor GT which may be disposed in a non-display area NA of the substrate 410. A plurality of pixels is arranged in the display area AA in a matrix form or the like. The non-display area NA is disposed around the display area AA. The gate driving thin film transistor GT drives the pixel driving thin film transistor DT and the switching thin film transistor ST disposed in the display area AA.

A semiconductor pattern included in the gate driving thin film transistor GT may be made of a polycrystalline silicon semiconductor formed through crystallization of a silicon semiconductor material. A semiconductor pattern included in each of the pixel driving thin film transistor DT and the switching thin film transistor ST may be made of an oxide semiconductor material.

A channel region in a silicon semiconductor pattern and a channel region in an oxide semiconductor pattern are defined through ion doping. In the present disclosure, the silicon semiconductor pattern is defined through patterning of a silicon semiconductor material deposited on a buffer layer 411 using a photo process. In addition, the oxide semiconductor pattern is defined through patterning of an oxide semiconductor material deposited on a first insulating layer 417 using a photo process.

When a semiconductor pattern is formed using a polycrystalline semiconductor material, an impurity implementation process and a high-temperature thermal treatment process are required. On the other hand, when a semiconductor pattern is formed using an oxide semiconductor material, a thermal treatment process is performed at a relatively low temperature. Accordingly, it is preferred that the polycrystalline semiconductor pattern be first formed because the process of forming the polycrystalline semiconductor pattern is performed under severe conditions, and the oxide semiconductor pattern be subsequently formed.

In addition, the polycrystalline semiconductor material may exhibit degradation of characteristics thereof when there are pores therein due to a manufacturing process thereof. In this case, therefore, it is necessary to perform a process for filling the pores with hydrogen through a hydrogenation process. On the other hand, in the oxide semiconductor material, oxygen pores remaining without covalent bonding may function as carriers. Therefore, a thermal treatment process for stabilizing the oxide semiconductor material under the condition that the oxide semiconductor material possesses the oxygen pores is needed.

In the hydrogenation process, a silicon nitride layer including a large amount of hydrogen particles is deposited on the polycrystalline semiconductor material. It is preferred that a silicon oxide layer is deposited between the silicon nitride layer and the oxide semiconductor material. In this case, it may be possible to prevent the hydrogen particles from being diffused into the oxide semiconductor material due to the thermal treatment process and, as such, to stabilize the resultant oxide semiconductor device.

The photo process, which will be described hereinafter, means a photolithography process including photomask alignment, exposure, development, and etching processes.

Referring to FIG. 4A, in the thin film transistor substrate for a display device according to the first embodiment of the present disclosure, the substrate 410 thereof may be constituted by a multilayer structure in which an organic layer and an inorganic layer are alternately stacked. For example, the substrate 410 may have a structure in which an organic layer made of, for example, polyimide, and an inorganic layer made of, for example, silicon oxide (SiO2), are alternately stacked. The buffer layer 411 is formed on the substrate 410. The buffer layer 411 may function to block moisture, etc., penetrating from an exterior thereof. The buffer layer 411 may be formed by depositing an inorganic insulating layer such as a silicon oxide layer in a number of at least one layer.

In addition, the thin film transistor substrate according to the first embodiment of the present disclosure includes the gate driving thin film transistor GT, the pixel driving thin film transistor DT, and the switching thin film transistor ST which are disposed over the substrate 410 while being spaced apart from one another. The transistors GT, DT, and ST may be disposed to be spaced apart from one another by a great distance, or may be disposed to be spaced apart from one another by a relatively small distance and, as such, to be disposed adjacent to one another.

The pixel driving thin film transistor DT includes a first active pattern 423 disposed on the first insulating layer 417, a first gate electrode 424 formed on the first insulating layer 417 and a second insulating layer 418, which cover a first light shielding pattern 422, while overlapping with the first active pattern 423, and a first source electrode 425S and a first drain electrode 425D disposed on a third insulating layer 419 covering the first gate electrode 424. The first gate electrode 424, the first source electrode 425S, and the first drain electrode 425D may be disposed on the same layer.

The first active pattern 423 of the pixel driving thin film transistor DT, which is formed by a portion of an oxide semiconductor pattern, includes a first channel region 423a, a first drain region 423c, and a first source region 423b. The first source region 423b and the first drain region 423c have conductivity and are formed through an ion doping process.

Meanwhile, the first light shielding pattern 422 is formed between the first active pattern 423 and the buffer layer 411. The first light shielding pattern 422 prevents light incident from an exterior thereof from being irradiated onto the first active pattern 423, thereby preventing the first active pattern 423 sensitive to external light from malfunctioning. The first light shielding pattern 422 is made of a silicon semiconductor material, and may have conductivity through ion doping.

The thin film transistor in which the active pattern thereof is made of an oxide semiconductor material is an N-type thin film transistor. In this regard, when P-type impurity ions are implemented in the first light shielding pattern 422 constituted by a semiconductor material layer, the Fermi-level of the semiconductor material layer is lowered. In addition, the Fermi-level of the first active pattern 423 corresponding to the first light shielding pattern 422 is also lowered in order to achieve a Fermi-level balance in a thermal equilibrium state. Accordingly, a threshold voltage Vth required to turn on the driving thin film transistor may increase.

The driving thin film transistor requires a very high threshold voltage due to the design thereof, as compared to other switching thin film transistors in the pixel thereof. In a general case, the switching thin film transistor has a threshold voltage approximate to 0 V, whereas the driving thin film transistor requires a threshold voltage of 1 V or more. In this regard, the pixel driving thin film transistor DT of the present disclosure has an advantage in that a threshold voltage thereof may be increased because the first light shielding pattern 422, which is a semiconductor material layer doped to have P-type conductivity, is provided under the first active pattern 423.

It is preferred that the first light shielding pattern 422 be formed vertically under the first active pattern 423, to overlap with the first active pattern 423. In addition, the first light shielding pattern 422 may be formed to have a greater size than that of the first active pattern 423 such that the first light shielding pattern 422 completely overlaps the first active pattern 423.

A semiconductor material has a lower reflectivity than that of a metal material. Accordingly, when the first light shielding pattern 422 is constituted by a semiconductor material, it may be possible to reduce a phenomenon in which external light is incident on the first active pattern 423 after being reflected by the first light shielding pattern 422, as compared to the case in which the first light shielding pattern 422 is constituted by a metal material.

Meanwhile, the first source electrode 425S of the pixel driving thin film transistor DT is electrically connected to the first light shielding pattern 422. When the first light shielding pattern 422 is electrically connected to the first source electrode 425S, the following additional effect may be obtained.

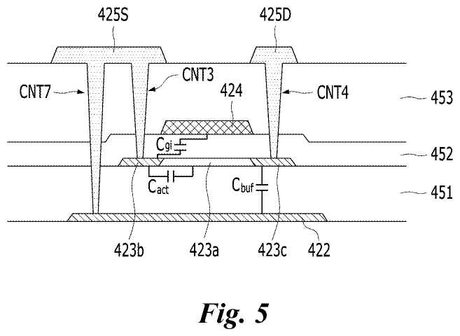

Referring to FIG. 5, as the first source region 423b and the first drain region 423c of the first active pattern 423 become conductive, a parasitic capacitance Cact is generated in the first active pattern 423 in an on/off operation. In addition, a parasitic capacitance Cgi is generated between the first gate electrode 424 and the first active pattern 423. In addition, a parasitic capacitance Cbuf is generated between the first light shielding pattern 422 electrically connected to the first source electrode 425S and the first active pattern 423.

Since the first active pattern 423 and the first light shielding pattern 422 are electrically interconnected by the first source electrode 425S, the parasitic capacitance Cact and the parasitic capacitance Cbuf are connected in parallel, and the parasitic capacitance Cact and the parasitic capacitance Cgi are connected in series. In addition, when a gate voltage of Vgat is applied to the first gate electrode 424, an effective voltage Veff actually applied to the first active pattern 423 satisfies the following expression.

$$Δ {V}_{e f f} = \frac{{C}_{g i}}{{C}_{g i} + {C}_{b u f} + {C}_{a c t}} \times Δ {V}_{g a t} \qquad [ Expression ]$$

Thus, the effective voltage Veff is inversely proportional to the parasitic capacitance Cbuf and, as such, it may be possible to adjust the effective voltage Veff applied to the first active pattern 423 by adjusting the parasitic capacitance Chuf.

That is, when the first light shielding pattern 422 is disposed near the first active pattern 423, to increase the parasitic capacitance Cbuf, it may be possible to reduce an actual value of current flowing through the first active pattern 423.

Reduction in the effective value of current flowing through the first active pattern 423 means that an s-factor may be increased, and means that a control range of the pixel driving thin film transistor DT controllable through the voltage Vgat applied to the first gate electrode 424 may be widened.

That is, when the first source electrode 425S of the pixel driving thin film transistor DT is electrically connected to the first light shielding pattern 422, and the first light shielding pattern 422 is disposed near the first active pattern 423, it may be possible to accurately control the organic light emitting element 470 even at low gray levels and, as such, to solve a problem of a Mura defect frequently generated at low gray levels.

Accordingly, in the first embodiment of the present disclosure, the parasitic capacitance Cbuf generated between the first active pattern 423 and the first light shielding pattern 422 may be greater than the parasitic capacitance Cgi generated between the first gate electrode 424 and the first active pattern 423.

Here, “s-factor” means a reciprocal value of a current variation to a gate voltage variation in an on/off transition period of a thin film transistor. That is, the s-factor may be a reciprocal value of a gradient of a curve in a characteristic graph of a drain current with respect to a gate voltage (V-I curve graph).

A small s-factor means a great gradient of a characteristic graph of a drain current with respect to a gate voltage. Accordingly, when a thin film transistor has a small s-factor, the thin film transistor may be turned on even by a low voltage and, as such, switching characteristics of the thin film transistor become better. However, sufficient grayscale expression is difficult because the thin film transistor reaches a threshold voltage within a short time.

A great s-factor means a small gradient of the characteristic graph of the drain current with respect to the gate voltage. Accordingly, when a thin film transistor has a great s-factor, the on/off response time of the thin film transistor may be degraded and, as such, switching characteristics of the thin film transistor may be degraded. However, sufficient grayscale expression may be possible because the thin film transistor reaches a threshold voltage after a relatively lengthened time.

In particular, the first light shielding pattern 422 may be disposed near the first active pattern 423 while being embedded in the first insulating layer 417. Of course, in the first embodiment, the first insulating layer 417 is illustrated as including a plurality of layers.

That is, the first insulating layer 417 may have a structure in which a first sub-insulating layer 417a and a second sub-insulating layer 417b are sequentially stacked. The first light shielding pattern 422 may be formed over the buffer layer 411 formed on the substrate 410. In addition, the first sub-insulating layer 417a completely covers the first light shielding pattern 422. In addition, the second sub-insulating layer 417b is formed over the first sub-insulating layer 417a.

The buffer layer 411 and the second sub-insulating layer 417b may be constituted by silicon oxide (SiO2).

The buffer layer 411 and the second sub-insulating layer 417b are constituted by silicon oxide (SiO2) not including hydrogen particles and, as such, prevent hydrogen particles from penetrating into the oxide semiconductor pattern during a thermal treatment procedure. When hydrogen particles penetrate into the oxide semiconductor pattern, reliability of the thin film transistor is degraded.

On the other hand, the first sub-insulating layer 417a may be constituted by silicon nitride (SiNx) having an excellent hydrogen particle collection ability. The first sub-insulating layer 417a may be formed only in a region where the first light shielding pattern 422 is formed, in order to completely encapsulate the first light shielding pattern 422. That is, a silicon nitride (SiNx) layer may be partially formed on the buffer layer 411 such that the silicon nitride (SiNx) layer completely covers an upper surface and a side surface of the first light shielding pattern 422. Alternatively, the first sub-insulating layer 417a may be formed over the entire upper surface on the buffer layer 411 on which the first light shielding pattern 422 is formed.

Silicon nitride (SiNx) is excellent in terms of hydrogen particle collection ability, as compared to silicon oxide (SiO2). When hydrogen particles penetrate into an active layer constituted by an oxide semiconductor material, resultant thin film transistors may have a problem in that the thin film transistors have different threshold voltages or different conductivities at channels thereof in accordance with formation positions thereof. That is, reliability of the thin film transistors is degraded. In particular, in the case of a driving thin film transistor, securing reliability is important because the driving thin film transistor directly contributes to operation of the light emitting element associated therewith.

Accordingly, in the first embodiment of the present disclosure, it may be possible to prevent degradation in reliability of the pixel driving thin film transistor DT caused by hydrogen particles by partially or completely forming, over the first sub-upper buffer layer 411, the first sub-insulating layer 417a covering the first light shielding pattern 422.

When the first sub-insulating layer 417a is partially deposited on the buffer layer 411, there is an advantage as follows.

That is, since the first sub-insulating layer 417a is formed of a material different from that of the buffer layer 411, layer blister may occur between the heterogeneous material layers when the first sub-insulating layer 417a is deposited over the entire upper surface of the display area. In order to solve such a problem, the first sub-insulating layer 417a may be selectively formed only in a region where the first light shielding pattern 422 is formed, for an enhancement in bonding force.

It is preferred that the first light shielding pattern 422 be formed vertically under the first active pattern 423, to overlap with the first active pattern 423. In addition, the first light shielding pattern 422 may be formed to have a size greater than that of the first active pattern 423, to completely overlap with the first active pattern 423.

Meanwhile in the first embodiment of the present disclosure, the first light shielding pattern 422 may include a semiconductor material layer doped with ions and, as such, becomes conductive. In addition, as the semiconductor material layer is doped with P-type ions, the threshold voltage of the pixel driving thin film transistor DT may be increased. In addition, as the first light shielding pattern 422 is disposed near the first active pattern 423, the parasitic capacitance Cbuf generated between the first active pattern 423 and the first light shielding pattern 422 may be increased. In this case, accordingly, the s-factor of the pixel driving thin film transistor DT is increased and, as such, the pixel driving thin film transistor DT may achieve grayscale expression even at low gray levels.

Meanwhile, the first gate electrode 424 of the pixel driving thin film transistor DT is insulated by the second insulating layer 418. The first source electrode 425S and the first drain electrode 425D are formed on a third insulating layer 419.

Although the first source electrode 425S and the first drain electrode 425D are shown as being disposed on the same layer, and the first gate electrode 424 is shown as being formed on a layer different from that of the first source electrode 425S and the first drain electrode 425D in the first embodiment of the present disclosure referring to FIG. 4A, all of the first gate electrode 424, the first source electrode 425S, and the first drain electrode 425D may also be disposed on the same layer.

The first source electrode 425S and the first drain electrode 425D are connected to a first source region 423b and a first drain region 423c via a third contact hole CNT3 and a fourth contact hole CNT4, respectively. In addition, the first light shielding pattern 422 is connected to the first source electrode 425S via a seventh contact hole CNT7.

The following description will be given in conjunction with, for example, the case in which a second active pattern 412 included in the gate driving thin film transistor GT is made of a polycrystalline semiconductor, and the gate driving thin film transistor GT is disposed in the non-display area NA.

The gate driving thin film transistor GT includes the second active pattern 412, which is disposed on the buffer layer 411 formed on the substrate 410, the first insulating layer 417, which insulates the second active pattern 412, a second gate electrode 413 disposed on the first insulating layer 417 while overlapping with the second active pattern 412, a plurality of insulating layers, for example, the second insulating layer 418 and the third insulating layer 419, formed on the second gate electrode 413, and a second source electrode 414S and a second drain electrode 414D disposed on the plurality of second insulating layers 418 and third insulating layers 419.

The second active pattern 412 is formed on the buffer layer 411. The second active pattern 412 may be used as an active pattern of the gate driving thin film transistor GT, and may be constituted by a polycrystalline semiconductor. The second active pattern 412 may include a second channel region 412a, and a second source region 412b and a second drain region 412c facing each other under the condition that the second channel region 412a is disposed therebetween.

The second active pattern 412 is insulated by the first insulating layer 417. The first insulating layer 417 is formed by depositing an inorganic insulating layer made of, for example, silicon oxide (SiO2), on the entire upper surface of the substrate 410 formed with the second active pattern 412 in a number of at least one layer. The first insulating layer 417 protects and insulates the second active pattern 412 from an exterior thereof.

The second gate electrode 413 is formed over the first insulating layer 417, and overlaps with the second active pattern 412. In addition, the second gate electrode 413 may be constituted by an oxide semiconductor material. In addition, the second gate electrode 413 may become conductive through ion doping, similarly to the first source/drain regions 423b and 423c. The plurality of second insulating layers 418 and third insulating layers 419 may be formed between the second gate electrode 413 and each of the second source electrode 414S and the second drain electrode 414D.

Referring to FIG. 4A, the plurality of second insulating layers 418 and third insulating layers 419 may include the second insulating layer 418 contacting an upper surface of the second gate electrode 413, and the third insulating layers 419 sequentially stacked on the second insulating layer 418.

The second source electrode 414S and the second drain electrode 414D are disposed on the third insulating layer 419. The second source electrode 414S and the second drain electrode 414D are connected to the second active pattern 412 via a first contact hole CNT1 and a second contact hole CNT2. The first contact hole CNT1 and the second contact hole CNT2 expose the second source region 412b and the second drain region 412c of the second active pattern 412, respectively, while extending through the first insulating layer 417, the second insulating layer 418, and the third insulating layer 419.

Meanwhile, the switching thin film transistor ST includes a third active pattern 433, a third gate electrode 444, a third source electrode 445S, and a third drain electrode 445D.

The third active pattern 433 includes a third channel region 433a, and a third source region 433b and a third drain region 433c disposed adjacent to the third channel region 433a under the condition that the third channel region 433a is disposed therebetween. The third source/drain regions 433b and 433c become conductive through ion doping, similarly to the first source/drain regions 423b and 423c.

The third gate electrode 444 is disposed over the third active pattern 433 under the condition that the second insulating layer 418 is interposed therebetween.

The third source electrode 445S and the third drain electrode 445D may be disposed on the same layer as that of the second source electrode 414S and the second drain electrode 414D. That is, the second source/drain electrodes 414S and 414D and the third source/drain electrodes 445S and 445D may be disposed on the third insulating layer 419.

In addition, the third source/drain electrodes 445S and 445D may be disposed on the same layer as that of the third gate electrode 444. That is, the third source/drain electrodes 445S and 445D may be simultaneously formed on the third insulating layer 419, using the same material.

In addition, a second light shielding pattern 432 may be disposed under the third active pattern 433.

The second light shielding pattern 432 may have the same configuration as that of the first light shielding pattern 422. That is, the second light shielding pattern 432 may have a single-layer structure of a silicon semiconductor material layer.

The second light shielding pattern 432 may be doped with P-type impurity ions, to have conductivity, and, as such, may function as a gate.

The second light shielding pattern 432 is disposed under the third active pattern 433 while overlapping with the third active pattern 433 in order to protect the third active pattern 433 from light incident from an exterior thereof.

The third gate electrode 444 and the second light shielding pattern 432 may be electrically interconnected and, as such, may constitute a dual gate. Referring to FIG. 4A, when the third gate electrode 444 is formed, the third gate electrode 444 is connected to the second light shielding pattern 432 via an eleventh contact hole CNT11. In this case, channels are formed over and under the third channel region 433a and, as such, stable supply of drain current may be achieved.

Since the second light shielding pattern 432 includes a semiconductor material layer doped with P-type impurity ions, it may be possible to increase the threshold voltage of the switching thin film transistor ST including the oxide semiconductor pattern. In other words, as the second light shielding pattern 432 is doped with P-type impurity ions, to have conductivity, the Fermi-level thereof is lowered, and the Fermi-level of the third active pattern 433 corresponding to the second light shielding pattern 432 is also lowered. Accordingly, the threshold voltage of the switching thin film transistor ST is increased. In particular, in the first embodiment of the present disclosure, a great effect is exhibited when the switching thin film transistor ST is a sampling transistor connected to a gate node of the pixel driving thin film transistor DT. The sampling transistor functions to provide a data voltage to one electrode of the storage capacitor during a sampling period. For example, the first switching thin film transistor ST1 shown in FIG. 3 is the sampling transistor.

The sampling transistor is known as a very sensitive transistor in which a channel thereof is opened even at a low voltage. In the first embodiment of the present disclosure, since the second light shielding pattern 432, which includes the semiconductor material layer doped with P-type impurity ions, is disposed under the third active pattern 433 in the switching thin film transistor ST, it may be possible to increase the threshold voltage of the switching thin film transistor ST and, as such, there is an advantage in that design freedom of an internal compensation circuit configuration may be enhanced.

A storage capacitor Cst stores a data voltage applied thereto via a data line for a predetermined period, and then provides the stored data voltage to a light emitting element 470.

The storage capacitor Cst includes two electrodes corresponding to each other, and a dielectric disposed between the two electrodes. The storage capacitor Cst includes a first electrode 443 disposed on the same layer as the second gate electrode 413 and made of the same material as that of the second gate electrode 413, and a second electrode 442 facing the first electrode 443 while overlapping with the first electrode 443.

The first insulating layer 417 may be interposed between the first electrode 443 and the second electrode 442 of the storage capacitor Cst.

The first electrode 443 of the storage capacitor Cst has conductivity through ion doping, similarly to the second gate electrode 413 of the gate driving thin film transistor GT.

In addition, the first electrode 443 may be electrically connected to the first source electrode 423b via an eighth contact hole CNT8 and the third contact hole CNT3. The first electrode 443 may be electrically connected to the first light shielding pattern 422 via the seventh contact hole CNT7 and the eighth contact hole CNT8.

In addition, the second electrode 442 of the storage capacitor Cst is formed on the same layer as that of the first light shielding pattern 422, the second light shielding pattern 432, and the second active pattern 412 and, as such, there is an advantage in that the number of mask processes is reduced. The method of forming the second electrode 442 is identical to the method of forming the first light shielding pattern 422 and the second light shielding pattern 432.

Hereinafter, a sequence of processes for forming the pixel driving thin film transistor DT, the switching thin film transistor ST, the storage capacitor Cst, and the gate driving thin film transistor GT will be described with reference to FIGS. 4B, 4C, 4D, and 4E.

Referring to FIG. 4B, a buffer layer 411 is deposited over the entire upper surface of a substrate 410. Thereafter, a first mask process is performed. The mask used in the first mask process is a half-tone mask and, as such, may form a photoresist PR while adjusting a transmission amount of light in a desired region such that the photoresist PR has a thickness greater or smaller than that of other regions. A silicon semiconductor material is deposited over the substrate 410 formed with the buffer layer 411. A photoresist PR is then coated on the silicon semiconductor material. Only regions where patterns will be formed are then irradiated with light, using a first mask. In this case, transmission amounts of light radiated to portions of the photoresist PR disposed in regions where a first light shielding pattern 422, a second light shielding pattern 432, and a second electrode 442 will be formed are smaller than a transmission amount of light radiated to a portion of the photoresist PR disposed on a second active pattern 412. When a development process is performed, portions of the photoresist PR in regions irradiated with greater transmission amounts of light are dissolved in smaller amounts by a development solution. When the development process is performed under the above-described condition, thicknesses of the portions of the photoresist PR disposed on the regions where the first light shielding pattern 422, the second light shielding pattern 432, and the second electrode 442 will be formed are smaller than a thickness of the portion of the photoresist PR disposed in a region where the second active pattern 412 will be formed, as shown in FIG. 4B. Through an etching process, a silicon semiconductor material region where the photoresist PR does not remain is removed.

Referring to FIG. 4C, an ashing process is performed to partially remove the photoresist PR such that only the portion of the photoresist PR disposed on the second active pattern 412 remains. Subsequently, an ion doping process is performed such that the silicon semiconductor material has conductivity. In this case, the photoresist PR remaining on the second active pattern 412 functions as a mask, thereby preventing the second active pattern 412 from being doped with ions. Accordingly, only the first light shielding pattern 422, the second light shielding pattern 432, and the second electrode 442 become conductive, except for the second active pattern 412.

Referring to FIG. 4D, a first insulating layer 417 is deposited on the entire upper surface of the substrate 410, to cover the silicon semiconductor patterns. An oxide semiconductor material is then coated over the entire upper surface of the first insulating layer 417. A photoresist is then coated on the oxide semiconductor material. Light is irradiated onto only regions where the first active pattern 423, the third active pattern 433, the second gate electrode 413, and the first electrode 443 will be formed, using a second mask. Through development, a portion of the photoresist not irradiated with light is removed. Thereafter, the oxide semiconductor material disposed in a region where the photoresist portion has been removed is etched through an etching process. The substrate 410 is then doped with ions under the condition that the photoresist remains on the oxide semiconductor material disposed only in the regions where the first active pattern 423, the third active pattern 433, the second gate electrode 413, and the first electrode 443 will be formed. During the ion doping, the second gate electrode 413 and the photoresist disposed on the second active pattern 412 function as a mask. In this case, portions of the second active pattern 412 not overlapping with the second gate electrode 413 become conductive and, as such, form a second source electrode 412b and a second drain electrode 412c. Thereafter, the remaining photoresist is removed through a stripping process and, as such, the first active pattern 423, the third active pattern 433, the second gate electrode 413, and the first electrode 443 are formed.

Referring to FIG. 4E, a second insulating layer 418 is then deposited on the first insulating layer 417. A metal material is deposited on the second insulating layer 418, and a photoresist is then formed on the metal material. Using a third mask, light is then radiated only to regions where a first gate electrode 424 and a third gate electrode 444 will be formed. Through development, a portion of the photoresist not irradiated with light is removed. Through an etching process, the metal material disposed in the region where the photoresist portion has been removed is then etched. Subsequently, the remaining photoresist is removed through a stripping process and, as such, the first gate electrode 424 and the third gate electrode 444 are formed. When ion doping is performed in this state, the first gate electrode 424 and the second gate electrode 413 function as a mask and, as such, oxide semiconductor patterns disposed under the first gate electrode 424 and the second gate electrode 413 without overlapping therewith become conductive. Accordingly, portions of the oxide semiconductor patterns form first source/drain regions 423b and 424c and third source/drain regions 433b and 433c. Since there is no gate electrode functioning as a mask during ion doping of oxide semiconductor patterns disposed on the second insulating layer 418 while being included in a gate driving thin film transistor GT and a capacitor Cst, all of the oxide semiconductor patterns become conductive through an ion doping process, thereby forming the second gate electrode 413 and the first electrode 443.

Referring to FIG. 4B, all of the first light shielding pattern 422, the second light shielding pattern 432, the second electrode 442, and the second active pattern 412 formed on the buffer layer 411 may be disposed on the same layer, and may include a silicon semiconductor material. In conventional cases, a mask for formation of a light shielding pattern is required when a pixel driving thin film transistor DT, a switching thin film transistor ST, or a gate driving thin film transistor GT requires such a light shielding pattern in accordance with purposes thereof. In the case of the first embodiment of the present disclosure, however, the first light shielding pattern 422, the second light shielding pattern 432, the second electrode 442, and the second active pattern 412 may be formed through the same process and, as such, the number of processes and mask costs may be reduced.

Referring to FIG. 4D, all of the first active pattern 423, the third active pattern 433, the second gate electrode 413, and the first electrode 443 formed on the first insulating layer 417 may be disposed on the same layer, and may include an oxide semiconductor material.

Meanwhile, referring to FIG. 4A, a first planarization layer PLN1 may be formed over the substrate 410 on which the pixel driving thin film transistor DT and the switching thin film transistor ST are disposed. Although the first planarization layer PLN1 may be formed of an organic material such as photoacryl, the first planarization layer PLN1 may also be constituted by a plurality of layers constituted by an inorganic layer and an organic layer. A connection electrode 426 is formed over the first planarization layer PLN1. The connection electrode 426 electrically interconnects an anode 471, which is one constituent element of a light emitting element 470, and the pixel driving thin film transistor DT via a ninth contact hole CNT9 formed in the first planarization layer PLN1.

A conductive layer used to form the connection electrode 426 may constitute a part of various link lines disposed in a bending area BA. Various lines formed in the substrate 410 may be formed by separate metal patterns formed on the same layer as a layer on which the first light shielding pattern 422, the second light shielding pattern 432, and the second active pattern 412 are formed. Each of these metal patterns may be constituted by a single layer or multiple layers made of one of molybdenum (Mo), aluminum (Al), chromium (Cr), gold (Au), titanium (Ti), nickel (Ni), neodymium (Nd), and copper (Cu) or an alloy thereof. A second planarization layer PLN2 may be formed over the connection electrode 426. Although the second planarization layer PLN2 may be formed of an organic material such as photoacryl, the second planarization layer PLN2 may also be constituted by a plurality of layers constituted by an inorganic layer and an organic layer.

The anode 471 is formed on the second planarization layer PLN2. The anode 471 is electrically connected to the connection electrode 426 via a tenth contact hole CNT10 formed in the second planarization layer PLN2.

The anode 471 may be constituted by a single layer or multiple layers made of a metal such as Ca, Ba, Mg, Al, Ag, etc., or an alloy thereof. The anode 471 is connected to the first drain electrode 425D of the pixel driving thin film transistor DT and, as such, an image signal from the outside is applied thereto.

In addition to the anode 471, a cathode connection electrode 474, which electrically interconnects a common voltage line VSS and a cathode 473, may be further provided in the non-display area NA.

Functions of the anode 471 and the cathode 473 may be interchanged in accordance with voltages applied thereto at different levels in accordance with different display devices.

A bank layer 460 is formed over the second planarization layer PLN2. The bank layer 460 is a kind of barrier, and may partition sub-pixels, thereby preventing light of particular colors output from adjacent ones of the sub-pixels from being output in a mixed state.

An organic light emitting layer 472 is formed on a surface of the anode 471 and a portion of an inclined surface of the bank layer 460. The organic light emitting layer 472 may be an R-organic light emitting layer configured to emit red light, a G-organic light emitting layer configured to emit green light, or a B-organic light emitting layer configured to emit blue light, which is formed at each sub-pixel. In addition, the organic light emitting layer 472 may be a W-organic light emitting layer configured to emit white light.

The organic light emitting layer 472 may include not only a light emitting layer, but also an electron injection layer and a hole injection layer respectively configured to inject electrons and holes into the light emitting layer, an electron transportation layer and a hole transportation layer respectively configured to transport electrons and holes to an organic layer, etc.

The cathode 473 is formed over the organic light emitting layer 472. The cathode 473 may be made of a transparent conductive material such as indium tin oxide (ITO) or indium zinc oxide (IZO), or a thin metal allowing transmission of visible light therethrough, without being limited thereto.

An encapsulation layer 480 is formed over the cathode 473. The encapsulation layer 480 may be constituted by a single layer formed of an inorganic layer, a double layer of inorganic layer/organic layer, or a triple layer of inorganic layer/organic layer/inorganic layer. The inorganic layer may be constituted by an inorganic material such as SiNx, SiX, or the like, without being limited thereto. In addition, the organic layer may be constituted by an organic material such as polyethylene terephthalate, polyethylene naphthalate, polycarbonate, polyimide, polyethylene sulfonate, polyoxymethylene, polyarylate, etc., or a mixture thereof, without being limited thereto.

In FIG. 4A, an embodiment of the encapsulation layer 480 is illustrated as being constituted by a triple layer of inorganic layer 481/organic layer 482/inorganic layer 483.

A cover glass may be disposed over the encapsulation layer 480, and may be attached to the encapsulation layer 480 by an adhesive layer. Although any material may be used as the adhesive layer, so long as the material exhibits excellent attachment force while being excellent in terms of heat resistance and water resistance, a thermosetting resin such as an epoxy-based compound, an acrylate-based compound, or an acryl-based rubber may be used in the present disclosure. Alternatively, a photo-curable resin may be used as the adhesive. In this case, the adhesive layer is cured through irradiation of the adhesive layer with light such as ultraviolet light.

The adhesive layer may not only serve to assemble the substrate 410 and the cover glass, but also to function as an encapsulator for preventing penetration of moisture into an interior of the display.

The cover glass may be an encapsulation cap for encapsulating the display device, and may use a protective film such as a polystyrene (PS) film, a polyethylene (PE) film, a polyethylene naphthalate (PEN) film, a polyimide (PI) film, or the like, and may use glass.

Ions used in the ion doping may be boron ions.

As apparent from the above description, in accordance with an exemplary embodiment of the present disclosure, a silicon semiconductor pattern is formed on a buffer layer, and light shielding patterns of a pixel driving thin film transistor and a switching thin film transistor are then formed by processing portions of the silicon semiconductor pattern such that the portions of the silicon semiconductor pattern have conductivity. Accordingly, an additional mask for formation of the light shielding patterns is not used and, as such, costs for production of a display device are reduced.

In addition, in accordance with the exemplary embodiment of the present disclosure, in a procedure of forming the silicon semiconductor pattern for formation of the light shielding patterns of the pixel driving thin film transistor and the switching thin film transistor, a silicon semiconductor pattern, which is disposed under a gate driving thin film transistor, may be formed simultaneously with the former silicon semiconductor pattern, without using an additional silicon semiconductor pattern formation procedure. Accordingly, stack structures, planar design, and processes are simplified and, as such, there are effects of preventing failure occurring due to processes while reducing tact time and costs.

Effects of the present disclosure are not limited to the above-described effects. Other effects not described in the present disclosure may be readily understood by those skilled in the art from the appended claims.

It will be apparent to those skilled in the art that various modifications and variations can be made in the present disclosure without departing from the spirit or scope of the present disclosure. Thus, it is intended that the present disclosure cover the modifications and variations of the present disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor substrate, comprising:
a substrate including a display area and a non-display area adjacent to the display area;
a pixel driving thin film transistor in the display area;
a buffer layer on the substrate, the buffer layer including at least one inorganic insulating layer;
a first insulating layer on the buffer layer, the first insulating layer including at least one inorganic insulating layer; and
a second insulating layer on the first insulating layer, the second insulating layer including at least one inorganic insulating layer,
wherein the pixel driving thin film transistor comprises:
a first active pattern on the first insulating layer;
a first gate electrode on the second insulating layer, the first gate electrode overlapping with the first active pattern;
a first light shielding pattern under the first active pattern, the first light shielding pattern overlapping with the first active pattern; and
a first source electrode and a first drain electrode electrically connected to the first active pattern,
wherein the first light shielding pattern is electrically connected to the first source electrode,
wherein the first active pattern includes an oxide semiconductor material, and
wherein the first light shielding pattern includes a semiconductor material that is conductive.

2. The thin film transistor substrate according to claim 1, further comprising a gate driving thin film transistor on the non-display area,
wherein the gate driving thin film transistor comprises:
a second active pattern on the buffer layer; and
a second gate electrode on the first insulating layer,
wherein the second active pattern includes a polycrystalline semiconductor material, and
wherein the second gate electrode includes an oxide semiconductor material that is conductive.

3. The thin film transistor substrate according to claim 2, further comprising a switching thin film transistor in the display area,
wherein the switching thin film transistor comprises:
a second light shielding pattern on the buffer layer;
a third active pattern on the first insulating layer; and
a third gate electrode overlapping with the third active pattern on the second insulating layer,
wherein the third active pattern includes an oxide semiconductor material,
wherein the second active pattern includes a semiconductor material that is conductive, and
wherein the second light shielding pattern and the third gate electrode are electrically connected.

4. The thin film transistor substrate according to claim 3, wherein the first light shielding pattern and the second light shielding pattern is a polycrystalline semiconductor material doped with P-type ions.

5. The thin film transistor substrate according to claim 3, further comprising a capacitor electrically connected to the pixel driving thin film transistor,
wherein the capacitor comprises a first capacitor electrode including an oxide semiconductor material that is conductive, and a second capacitor electrode including a polycrystalline silicon semiconductor material that is conductive.

6. The thin film transistor substrate according to claim 5, wherein:
the first capacitor electrode is on the first insulating layer; and
the second capacitor electrode is on the buffer layer.

7. The thin film transistor substrate according to claim 5, wherein the second active pattern, the first light shielding pattern, the second light shielding pattern, and the second capacitor electrode are disposed on a same layer and made of a same material.

8. The thin film transistor substrate according to claim 5, wherein the second gate electrode, the first active pattern, and the first capacitor electrode are disposed on a same layer and made of a same material.

9. The thin film transistor substrate according to claim 5, wherein the first active pattern comprises an N-type semiconductor material, and the first light shielding pattern comprises a P-type semiconductor material.

10. An organic light emitting display device, comprising:
a thin film transistor substrate including:
a substrate including a display area and a non-display area adjacent to the display area;
a pixel driving thin film transistor in the display area;
a buffer layer on the substrate, the buffer layer including at least one inorganic insulating layer;
a first insulating layer on the buffer layer, the first insulating layer including at least one inorganic insulating layer; and
a second insulating layer on the first insulating layer, the second insulating layer including at least one inorganic insulating layer; and
a light emitting element electrically connected to the pixel driving thin film transistor,
wherein the pixel driving thin film transistor comprises:
a first active pattern on the first insulating layer;
a first gate electrode on the second insulating layer, the first gate electrode overlapping with the first active pattern;
a first light shielding pattern under the first active pattern, the first light shielding pattern overlapping with the first active pattern; and
a first source electrode and a first drain electrode electrically connected to the first active pattern,
wherein the first light shielding pattern is electrically connected to the first source electrode,
wherein the first active pattern includes an oxide semiconductor material, and
wherein the first light shielding pattern includes a semiconductor material that is conductive.

11. The organic light emitting display device according to claim 10, further comprising a first planarization layer on the second insulating layer,
wherein the light emitting element is disposed on the first planarization layer, and
wherein the light emitting element comprises:
an anode disposed on the first planarization layer;
a cathode corresponding to the anode; and
an organic light emitting layer disposed between the anode and the cathode.

12. The organic light emitting display device according to claim 11, further comprising:
a common voltage line on the non-display area, the common voltage line providing a common voltage to the pixel driving thin film transistor; and
a cathode connection electrode electrically connecting the common voltage line to the cathode.

13. A method of manufacturing a thin film transistor substrate, comprising:
forming a buffer layer on a substrate including a display area and a non-display area adjacent to the display area;
forming a first light shielding pattern and a second active pattern, which are made of a first semiconductor material on the buffer layer;
forming a first insulating layer on the first light shielding pattern and the second active pattern;
forming a first active pattern and a second gate electrode, which are made of a second semiconductor material on the first insulating layer;
forming a second insulating layer on the first active pattern and the second gate electrode;
forming a first gate electrode on the second insulating layer, the first gate electrode overlapping with the first active pattern; and
forming a first source electrode, a first drain electrode, a second source electrode and a second drain electrode on the first gate electrode.

14. The method of manufacturing a thin film transistor substrate according to claim 13, further comprising:
forming a first electrode of a storage capacitor, which is made of the first semiconductor material on the buffer layer; and
forming a second electrode of the storage capacitor, which is made of the second semiconductor material on the first insulating layer.

15. The method of manufacturing a thin film transistor substrate according to claim 13, further comprising:
forming a second light shielding pattern, which is made of the first semiconductor material on the buffer layer; and
forming a third active pattern, which is made of the second semiconductor material on the first insulating layer.

16. The method of manufacturing a thin film transistor substrate according to claim 13, wherein the first semiconductor material is a polycrystalline semiconductor material, and the second semiconductor material is an oxide semiconductor material.

17. The method of manufacturing a thin film transistor substrate according to claim 13, wherein the forming a first light shielding pattern and the second active pattern made of the first semiconductor material on the first buffer layer comprises:
depositing the first semiconductor material on the buffer layer;
coating a photoresist on the first semiconductor material;
performing a photo process in the photoresist, such that a photoresist pattern is remained on the second active pattern and the first light shielding pattern is exposed; and
implanting ions in the first light shielding pattern, such that the first light shielding pattern is conductive.

18. The method of manufacturing a thin film transistor substrate according to claim 13, wherein the forming the first active pattern and the second gate electrode made of the second semiconductor material on the first insulating layer comprises:
depositing the second semiconductor material on the first insulating layer;
coating a photoresist on the second semiconductor material;
ashing the photoresist, such that the first active pattern and the second gate electrode are defined;
patterning the second semiconductor material, such that the first active pattern and the second gate electrode are formed;
doping the second active pattern exposed by the second gate electrode with an impurity; and
removing the photoresist on the first active pattern and the second gate electrode.

19. The method of manufacturing a thin film transistor substrate according to claim 13, wherein the forming the first gate electrode on the second insulating layer to overlap the first active pattern comprises:
forming the first gate electrode on the second insulating layer; and
conductorizing the first active pattern exposed from the first gate electrode by implanting ions.

20. A method of manufacturing an organic light emitting display device comprising:
forming a buffer layer on a substrate including a display area and a non-display area adjacent to the display area;
forming a first light shielding pattern and a second active pattern, which are made of a first semiconductor material on the buffer layer;
forming a first insulating layer on the first light shielding pattern and the second active pattern;
forming a first active pattern and a second gate electrode, which are made of a second semiconductor material on the first insulating layer;
forming a second insulating layer on the first active pattern and the second gate electrode;
forming a first gate electrode on the second insulating layer, the first gate electrode overlapping with the first active pattern; and
forming a first source electrode, a first drain electrode, a second source electrode and a second drain electrode on the first gate electrode;
forming a third insulating layer on the second insulating layer;
forming a first planarization layer on the third insulating layer,
forming a second planarization layer on the first planarization layer,
forming an anode on the second planarization layer;
forming an organic light emitting layer on the anode; and
forming a cathode on the organic light emitting layer,
wherein the anode is electrically connected to the first drain electrode.
